(19) United States
(12) Patent Application Publication
(10) Pub. No.: US 2025/0253808 A1
(43) Pub. Date: Aug. 7, 2025

(54) DOHERTY AMPLIFIER WITH ADAPTIVE BIASING

(71) Applicant: Qorvo US, Inc., Greensboro, NC (US)

(72) Inventors: Ming Ji, Melrose, MA (US); Douglas Andrew Teeter, Lexington, MA (US)

(21) Appl. No.: 18/855,205

(22) PCT Filed: May 8, 2023
(86) PCT No.: PCT/US2023/021341

§ 371 Date: Oct. 8, 2024

Related U.S. Application Data
(60) Provisional application No. 63/346,391, filed on May 27, 2022.

(51) Int. Cl. H03F 1/02; H03F 1/30; H03F 3/24; H04B 1/40

(52) U.S. Cl. CPC H03F 1/0288; H03F 1/0222; H03F 1/305; H03F 3/245; H04B 1/40; H03F 2200/451

(57) ABSTRACT

An amplifier is disclosed having a carrier amplifier and a peaking amplifier coupled in parallel with the carrier amplifier, wherein the peaking amplifier has peaking output transistors. A peaking power supply adaptive bias generator is coupled to bias control terminals of the peaking output transistors. The peaking power supply adaptive bias generator is configured to sense supply voltage to the peaking amplifier and increase bias currents to the peaking output transistors as the supply voltage decreases.

### RELATED APPLICATIONS

This application claims the benefit of provisional patent application Ser. No. 63/346,391, filed May 27, 2022, the disclosure of which is hereby incorporated herein by reference in its entirety.

### FIELD OF THE DISCLOSURE

The present disclosure relates to amplifier structures for maximizing power amplifier efficiency at low average output power and low power supply voltage operation.

### BACKGROUND

Compared with a conventional power amplifier, a symmetrical Doherty power amplifier improves power amplifier efficiency significantly at about 6 dB power back off from its peak continuous wave power. The Doherty power amplifier is usually configured to achieve best efficiency and best linearity at its maximum average power under signal modulation. However, Doherty power amplifier performance is often suboptimal at low average output power and low power supply voltage operation due to the insufficient self-biasing of the Doherty power amplifier's peaking amplifier.

When a Doherty power amplifier is configured to achieve best efficiency and best linearity at the Doherty power amplifier's maximum average power under signal modulation, the Doherty power amplifier performance is often suboptimal at low average output power and low power supply voltage (Vcc) operation due to insufficient self-biasing of the Doherty power amplifier's peaking amplifier. Although a gallium arsenide (GaAs) heterojunction bipolar transistor (HBT) Doherty power amplifier is able to improve continuous wave P1 dB power slightly at the high Vcc range (>3.5 V) compared with a conventional counterpart, the GaAs HBT Doherty power amplifier still exhibits significant amplitude modulation-amplitude modulation (AMAM) distortion and significant loss of P1 dB power (up to 6 dB) at low to mid Vcc range (<3.5 V). Thus, further improvement to the Doherty amplifier is needed because a cell phone's average power statistics is heavily distributed in the lower power region. As such, a new Doherty amplifier structure and method is needed to enable a Doherty power amplifier to operate over a wider supply voltage range that includes the low to mid Vcc range (<3.5 V).

### SUMMARY

An amplifier is disclosed having a carrier amplifier and a peaking amplifier coupled in parallel with the carrier amplifier, wherein the peaking amplifier has peaking output transistors. A peaking power supply adaptive bias generator is coupled to bias control terminals of the peaking output transistors. The peaking power supply adaptive bias generator is configured to sense supply voltage to the peaking amplifier and increase bias currents to the peaking output transistors as supply voltage decreases.

Those skilled in the art will appreciate the scope of the present disclosure and realize additional aspects thereof after reading the following detailed description in association with the accompanying drawings.

### BRIEF DESCRIPTION OF THE DRAWINGS

The accompanying drawing figures incorporated in and forming a part of this specification illustrate several aspects of the disclosure and, together with the description, serve to explain the principles of the disclosure.

FIG. 1 is a schematic showing a differential Doherty architecture in demonstration of supply adaptive biasing (dashed box).

FIGS. 2A to 2C show a continuous wave waveform simulation of differential Doherty power amplifier and conventional differential power amplifier, Fc=2593 MHz.

FIG. 2A is a graph showing a continuous wave power added efficiency referenced at a power amplifier output: Pin swept from −30 dBm to +10 dBm, in 1 dB steps, Vcc 1 V to 5.5 V in 0.5 V steps.

FIG. 2B is a graph showing a continuous wave amplitude modulation-amplitude modulation distortion of transmit.

FIG. 2C is a graph showing a memoryless average power tracking simulation of transmit: Signal: 100 MHz 5G cyclic prefix quadrature phase shift keyed (CP_QPSK) inner RB, MPR=1.5 dB.

FIG. 3 shows a graph from a GSMA report on handset transmit power distribution for Wideband Code Division Multiple Access and is a good approximation for 4G and 5G FR1 (frequency range 1) signals.

FIG. 4 is a schematic showing an embodiment of a bipolar junction transistor (BJT) with low leakage supply adaptive bias; the BJT devices can be replaced with field-effect transistors (FETs).

FIGS. 5A, 5B, 5C, and 5D are graphs showing direct current (DC) simulated supply adaptive biasing and peaking amplifier bias with sweeping power supply voltage (Vcc), based on an example gallium arsenide (GaAs) heterojunction bipolar transistor (HBT) embodiment: the power amplifier bias class is labelled in FIGS. 5C and 5D; Ven=2.8 V, Ireg2p=4.6 mA, Tambient=25° C.

FIGS. 6A and 6B show the total Vcc leakage current simulation of GaAs HBT Doherty power amplifier over temperature and Vcc: Ven=0 V, Ireg=0 A.

FIG. 6A is a graph showing a supply adaptive biasing leakage protection D2 and Q11 removed as baseline.

FIG. 6B is a graph showing a supply adaptive biasing (SAB) embodiment with D2 and Q11 included.

FIGS. 7A to 7F show Doherty power amplifier operation vs. instantaneous module output power at swept supply Vcc.

FIGS. 7A, 7B, and 7C are graphs showing a traditional Doherty power amplifier without supply adaptive biasing.

FIGS. 7D, 7E, and 7F are graphs showing a Doherty power amplifier with supply adaptive biasing: Pin: −30 dBm to +10 dBm, Fc=2593 MHz.

FIGS. 8A, 8B, 8C, and 8D are graphs showing a Doherty power amplifier overall performance simulation with and without supply adaptive biasing: Fc=2593 MHz.

FIG. 9 is a table that is a comparison of linear transmit output power in decibel-milliwatt (dBm).

FIGS. 10A, 10B, and 10C are graphs showing a Doherty power amplifier modulated signal simulation at module Avg Po=15 dBm in n41 band: Signal: 100 MHz 5G CP-QPSK inner RB; DC-DC converter eff=92% in computation of Ibatt.

FIG. 11 is a schematic showing another general embodiment of supply adaptive biasing; Ven is tied to Vreg or Ireg supply to power amplifier bias.

FIG. 12 is a schematic showing an alternative supply adaptive biasing embodiment with enabling device Q11 replaced with a FET device.

FIG. 13 is a schematic showing an alternative supply adaptive biasing embodiment with both Q10 and Q11 replaced with FET devices.

FIG. 14 is a schematic showing an alternative complementary metal oxide semiconductor supply adaptive biasing embodiment with Q10 and Q11 positions swapped.

FIG. 15 is a schematic of a wireless communication device that incorporates the Doherty amplifier of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to a supply adaptive biasing method for adapting the peaking amplifier bias current according to the sensed supply voltage (Vcc) to enable sufficient load modulation across a wide Vcc supply range. Furthermore, a saturation mode bipolar junction transistor device is placed inside the supply adaptive biasing to disable it in the off mode of the power amplifier. As a result, the Doherty power amplifier not only demonstrates improved amplitude modulation-amplitude modulation, amplitude modulation-phase modulation, and efficiency in the medium power to low power range but also shows specification-compliant supply leakage current (≤1.2 μA) at extreme Vcc and temperature conditions. Further still, the present disclosure relates to a method to implement low leakage automatic supply adaptive biasing in a Doherty amplifier for optimum average power tracking (APT) mid-power mode/low-power mode performance.

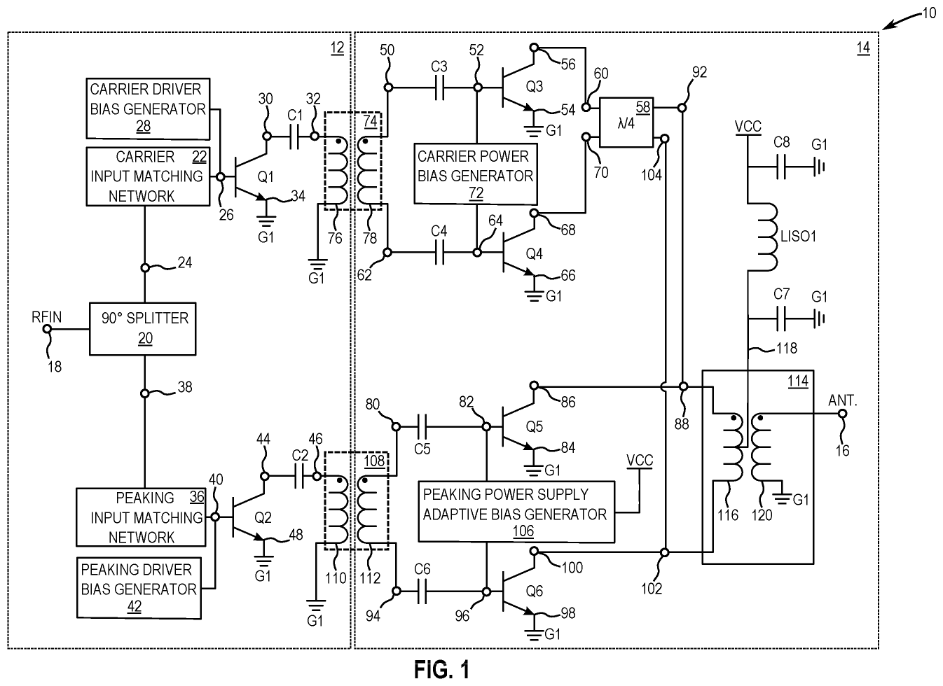

FIG. 1 is a schematic depicting a differential Doherty power amplifier 10 that is structured in accordance with the present disclosure. The Doherty power amplifier 10 is designed for a 5G handset transmit (TX) system in the n40 and n41 bands using a gallium arsenide (GaAs) heterojunction bipolar transistor (HBT) process. The Doherty power amplifier 10 has two stages of power amplification with a first stage 12 being single-ended and a second stage 14 being differential-ended. A specified continuous wave 1-dB gain compression power target is 33.5 dBm at an antenna port 16 labeled ANT.

The first stage 12 has a radio frequency (RF) signal input 18 labeled RFIN. A 90° splitter 20 is configured to direct a first portion of an RF signal arriving at the RF signal input 18 into a carrier signal path and direct a second portion of the RF signal into a peaking signal path. The carrier signal path includes a carrier driver transistor Q1 and a carrier input matching network 22 coupled between a carrier splitter output 24 of the 90° splitter 20 and a first driver base 26 of the carrier driver transistor Q1. A carrier driver bias generator 28 coupled to the first driver base 26 is configured to provide a substantially fixed bias for the carrier driver transistor Q1. A first coupling capacitor C1 is coupled between a first driver collector 30 of the carrier driver transistor Q1 and a first driver output 32. A first driver emitter 34 of the carrier driver transistor Q1 is coupled to a fixed voltage node G1, which in this exemplary embodiment is ground. The peaking signal path includes a peaking driver transistor Q2 and a peaking input matching network 36 coupled between a peaking splitter output 38 of the 90° splitter 20 and a second driver base 40 of the peaking driver transistor Q2. A peaking driver bias generator 42 coupled to the second driver base 40 is configured to provide a substantially fixed bias for the peaking driver transistor Q2. A second coupling capacitor C2 is coupled between a second driver collector 44 of the peaking driver transistor Q2 and a second driver output 46. A second driver emitter 48 of the peaking driver transistor Q2 is coupled to the fixed voltage node G1.

The second stage 14 includes a first carrier power transistor Q3 that is configured to amplify positive portions of the RF signal taking the carrier path. A third coupling capacitor C3 is coupled between a positive carrier input 50 and a positive carrier base 52. A positive carrier emitter 54 of the first carrier power transistor Q3 is coupled to the fixed voltage node G1. A positive carrier collector 56 is coupled to a quarter-wave transformer 58 by way of a first quarter-wave input 60. The second stage 14 further includes a second carrier power transistor Q4 that is configured to amplify negative portions of the RF signal taking the carrier path. A fourth coupling capacitor C4 is coupled between a negative carrier input 62 and a negative carrier base 64 of the second carrier power transistor Q4. A negative carrier emitter 66 is coupled to the fixed voltage node G1. A negative carrier collector 68 is coupled to the quarter-wave transformer 58 by way of a second quarter-wave input 70. The first carrier power transistor Q3 and the second carrier power transistor Q4 are referred to collectively as carrier output transistors.

A carrier power bias generator 72 is coupled between the positive carrier base 52 and the negative carrier base 64. The carrier power bias generator 72 is configured to provide substantially fixed bias to both the first carrier power transistor Q3 and the second carrier power transistor Q4. A carrier signal transformer 74 is coupled within the carrier signal path between the first stage 12 and the second stage 14. The carrier signal transformer 74 has a primary coil 76 coupled between the first driver output 32 and the fixed voltage node G1. The carrier signal transformer 74 has a secondary coil 78 coupled between the positive carrier input 50 and the negative carrier input 62.

The second stage 14 further includes a first peaking power transistor Q5 that is configured to amplify positive portions of the RF signal taking the peaking path. A fifth coupling capacitor C5 is coupled between a positive peaking input 80 and a positive peaking base 82. A positive peaking emitter 84 of the first peaking power transistor Q5 is coupled to the fixed voltage node G1. A positive peaking collector 86 is coupled to a positive output 88 that is further coupled to a first quarter-wave output 92 of the quarter-wave transformer 58. Amplified signals from the first carrier power transistor Q3 and the first peaking power transistor Q5 are summed together at the positive output 88.

The second stage 14 further includes a second peaking power transistor Q6 that is configured to amplify negative portions of the RF signal taking the peaking path. A sixth coupling capacitor C6 is coupled between a negative peaking input 94 and a negative peaking base 96 of the second peaking power transistor Q6. A negative peaking emitter 98 is coupled to the fixed voltage node G1. A negative peaking collector 100 is coupled to a negative output 102 that is further coupled to a second quarter-wave output 104. Amplified signals from the first peaking power transistor Q5 and the second peaking power transistor Q6 are summed together at the negative output 102.

A peaking power supply adaptive bias generator 106 is coupled between the positive peaking base 82 and the negative peaking base 96. The peaking power supply adaptive bias generator 106 is configured to provide bias to both the first peaking power transistor Q5 and the second peaking power transistor Q6. The first peaking power transistor Q5 and the second peaking power transistor Q6 are referred to collectively as peaking output transistors.

A peaking signal transformer 108 is coupled within the peaking signal path between the first stage 12 and the second stage 14. The peaking signal transformer 108 has a primary coil 110 coupled between the second driver output 46 and the fixed voltage node G1. The peaking signal transformer 108 has a secondary coil 112 coupled between the positive peaking input 80 and the negative peaking input 94. A balanced-unbalanced transformer (Balun) 114 has a balanced side coil 116 coupled between the positive output 88 and the negative output 102. The balanced side coil 116 has a supply tap 118 that is coupled to a supply voltage source VCC that supplies power to the first carrier power transistor Q3, the second carrier power transistor Q4, the first peaking power transistor Q5, and the second peaking power transistor Q6. A first bypass capacitor C7 is coupled between the supply tap 118 and the fixed voltage node G1. An isolation inductor LISO1 is coupled between the supply tap 118 and the voltage source VCC. A second bypass capacitor C8 is coupled between the voltage source VCC and the fixed voltage node G1. An unbalanced side coil 120 is coupled between the antenna port 16 and the fixed voltage node G1.

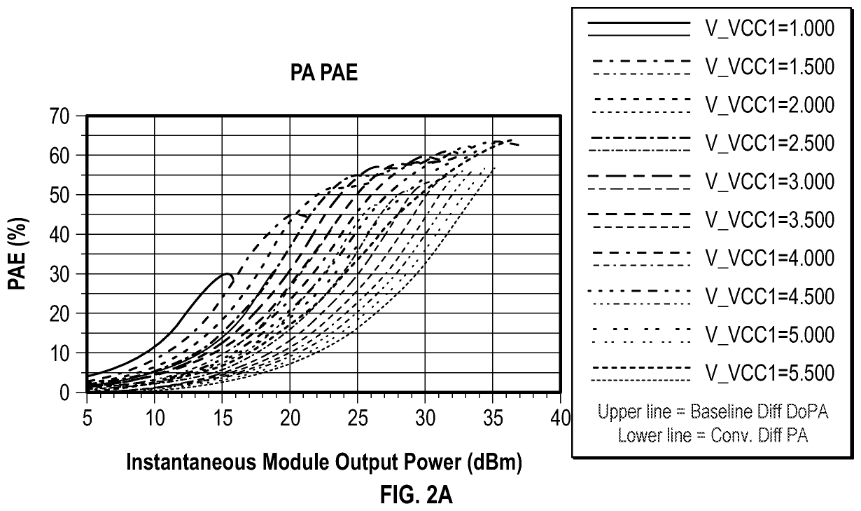

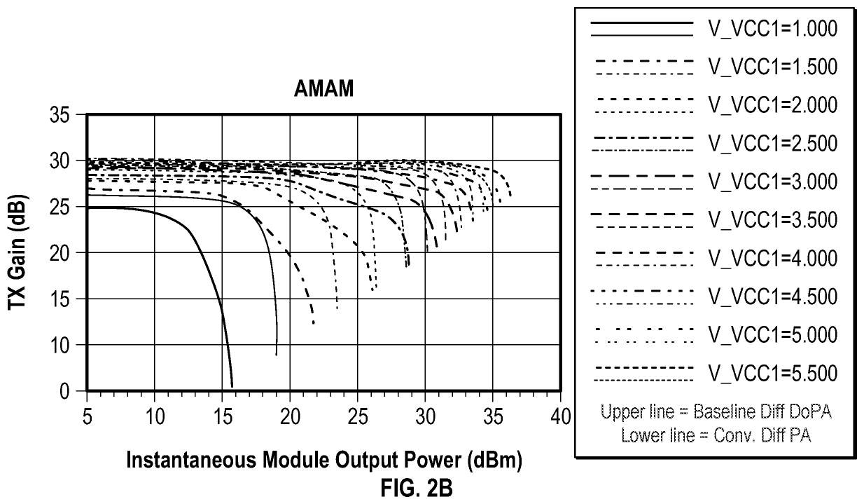

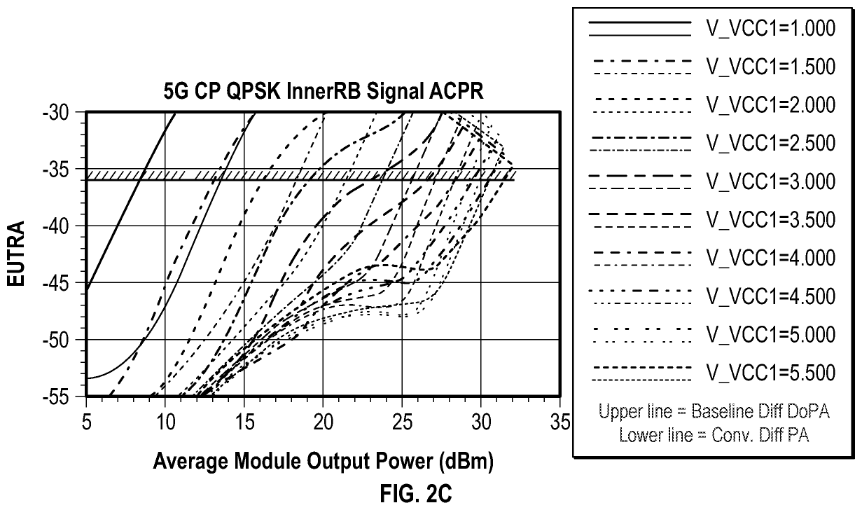

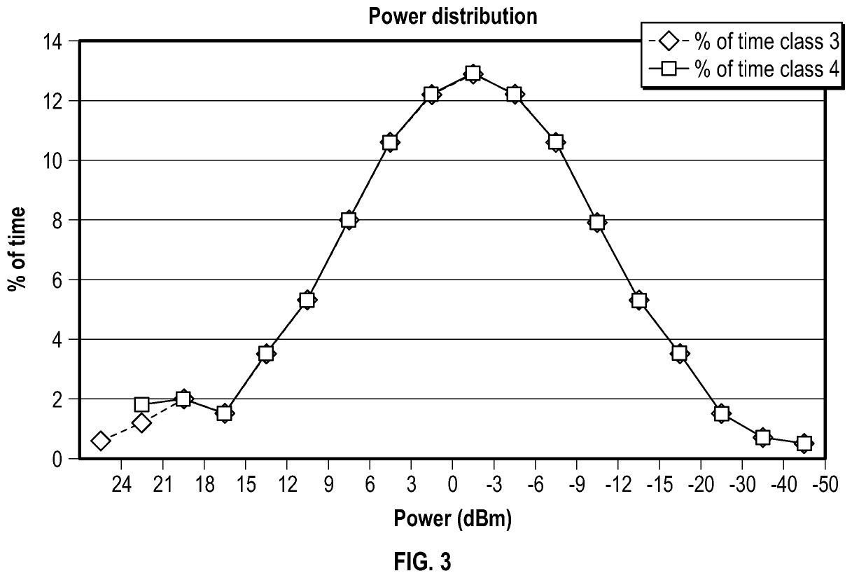

The Doherty power amplifier 10 depicted in FIG. 1 is designed for a 5G handset transmit (TX) module in the n40 and n41 bands, based on a GaAs HBT process. The Doherty power amplifier 10 has a continuous wave 1-dB gain compression power target (P1 dB) that is specified as 33.5 dBm at its output with a Vcc=5 V. FIG. 2A is a graph showing a simulated baseline Doherty power amplifier performance without supply adaptive biasing in comparison with a conventional differential power amplifier designed for the same bands. The baseline Doherty power amplifier has significant power backed off (PBO) power-added efficiency (PAE) improvement over the conventional power amplifier across the swept Vcc, as shown in FIG. 2A. However, a graph of transmitter gain versus instantaneous output power depicted in FIG. 2B points out a problem of the baseline Doherty power amplifier before supply adaptive biasing is implemented. Although the baseline Doherty power amplifier improves continuous wave P1 dB power slightly at the high Vcc range, which is >3.5 V in this example, the baseline Doherty amplifier exhibits significant amplitude modulation-amplitude modulation (AMAM) distortion and significant loss of P1 dB power up to 6 dB at low to mid Vcc range, which is <3.5 V in this example. FIG. 2C is a graph showing a transmit (TX) memoryless modulated signal simulation with an example 5G signal at 100 MHz cyclic prefix quadrature phase shift keyed (CP-QPSK) inner resource block. As expected from the continuous wave simulation, the baseline Doherty power amplifier loses 5 dB to 6 dB linear output power meeting the Evolved Universal Terrestrial Radio Access (EUTRA) target of −36 dBc) at low to mid Vcc range in comparison with the conventional power amplifier. The baseline Doherty power amplifier's performance gap, as illustrated in FIGS. 2A, 2B, and 2C, requires improvement because low power operation is critical to an average cell phone user's experience. The Global System for Mobile communication (GSM) Association published TX power probability distribution functions as depicted in FIG. 3 for Wideband Code Division Multiple Access (WCDMA). These published TX power probability distribution functions are a good approximation for 4G and 5G signals. Although a power amplifier is often optimized for peak power performance, statistically it has very little probability of operating there. Instead, the large probability happens between 10 dB to 50 dB below the peak power. Backed off power operation requires a lower supply voltage Vcc compared with peak power to reduce battery current draw.

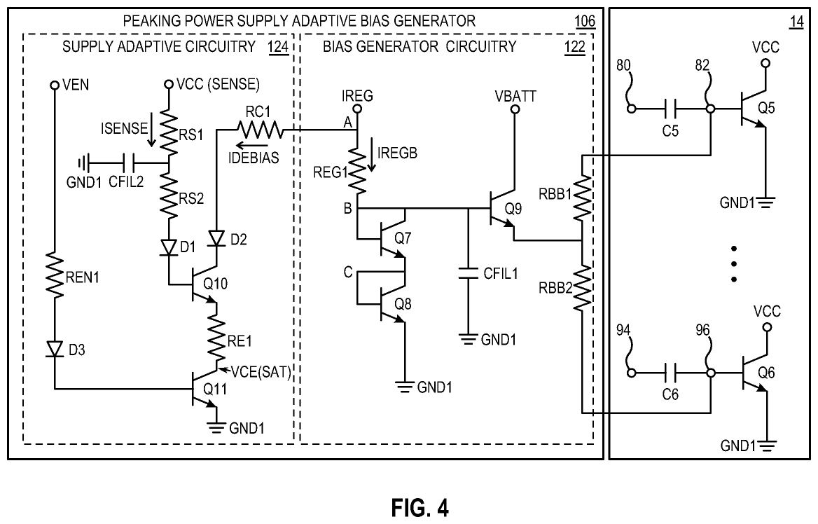

FIG. 4 is a detailed schematic of an exemplary embodiment of the peaking power supply adaptive bias generator 106 that controls the biases for the first peaking power transistor Q5 and the second peaking power transistor Q6 for the second stage 14 of the Doherty power amplifier 10 depicted in FIG. 1. Bias generator circuitry 122 and supply adaptive circuitry 124 make up the peaking power supply adaptive bias generator 106. The bias generator circuitry 122 has a seventh transistor Q7 and an eighth transistor Q8 that are both in a diode configuration and are coupled in series with a regulator resistor REG1 between a node labeled A and a fixed voltage node GND1. In operation, a current IREGB flows from a current regulator terminal IREG at a node labeled A. The current IREGB flows through the regulator resistor REG1. A ninth transistor Q9 configured as a bias generator transistor has a base coupled to a node labeled B. An emitter of the ninth transistor Q9 is coupled to the positive peaking base 82 through a first base resistor RBB1 and is coupled to the negative peaking base 96 through a second base resistor RBB2. A collector of the ninth transistor Q9 is coupled to a battery voltage VBATT. A first filter capacitor CFIL1 is coupled from the base of the ninth transistor Q9 and the fixed voltage node GND1.

In this exemplary embodiment, the supply adaptive circuitry 124 includes a tenth transistor Q10 that is referred to as a debias transistor and an eleventh transistor Q11 that is referred to as an enable transistor coupled in series between the node labeled A and the fixed voltage node GND1. A debias control in the form of a base or gate of the tenth transistor Q10 is coupled to a supply voltage sense terminal labeled VCC (SENSE) through a first sense resistor RS1, a second sense resistor RS2, and a first diode D1 that is referred to as a sense diode has a cathode coupled to the base of the tenth transistor Q10. A collector of the tenth transistor Q10 is coupled to the node labeled A through a debias current branch that in this exemplary embodiment includes a second diode D2 that is referred to as a debias diode and a first collector resistor RC1. In this exemplary embodiment, the node labeled A is a bias control node of the bias generator circuitry 122. However, in other embodiments the node labeled B is the bias control node to which the debias current branch is coupled. In this exemplary embodiment, a cathode of the second diode D2 is coupled to the tenth transistor Q10. A second filter capacitor CFIL2 is coupled between the fixed voltage node GND1 and a node between the first sense resistor RS1 and the second sense resistor RS2. A base of the eleventh transistor Q11 is coupled to an enable terminal labeled VEN through a third diode D3 that is referred to as an enable diode and an enable resistor REN1. A cathode of the third diode D3 is coupled to the base of the eleventh transistor Q11.

The sense current Isense is calculated by Equation 1 as follows:

$${I}_{sense} = \frac{{V}_{cc} - {V}_{F}^{D 1} - {V}_{BE}^{Q 10} - {V}_{CE}^{Sat}}{{R}_{s} + ( 1 + β ) \cdot {R}_{e}} \qquad EQ . 1$$

where β is the BJT device forward current gain in Equations 1 to 4.

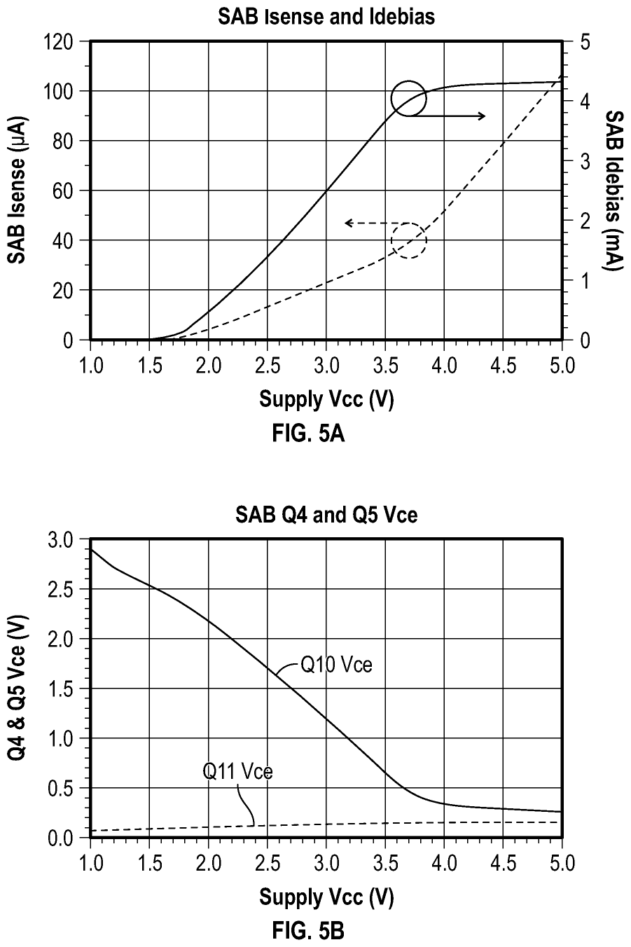

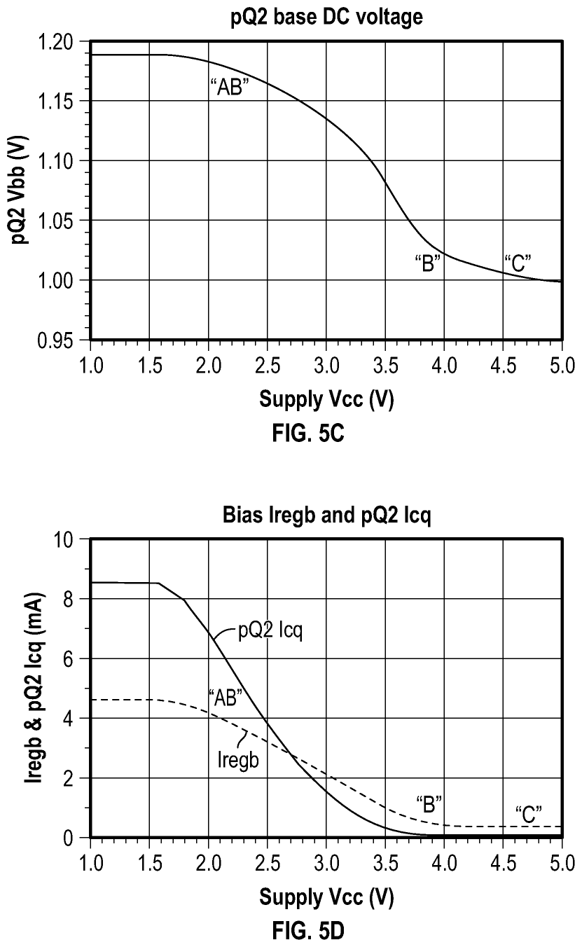

The present disclosure relates to a Vcc supply adaptive bias method to overcome the low-power performance degradation in the baseline Doherty power amplifier 10. As shown in FIG. 4, the peaking power supply adaptive bias generator 106 first senses the Vcc at a radio frequency (RF) filtered node VCC (SENSE) of a TX module. Rs1 and Cfil2 further reduce any stray RF coupling onto the sensed signal. Then the supply adaptive biasing derives and sinks a current Idebias that is related to Vcc, as shown in Equation 2. This Idebias is subtracted from the existing external bias Vreg or Ireg. For simplicity, Ireg is chosen for analysis. Therefore, the net Iregb (=Ireg−Idebias) that goes into the power amplifier bias network is dependent on Vcc as well. To have the desired Idebias vs Vcc profile, such as shown in FIG. 5A, a few elements of the supply adaptive biasing circuit are in use:
(i) Q10 generates the Idebias based on the sensed Vcc and works in the off mode below the Vcc threshold, in the active region in the mid Vcc region, and in the saturation mode in the high Vcc region.
(ii) D1 is used to control the Vcc threshold voltage for Idebias ramp down, which is ˜1.7 V in this example implementation (see FIG. 5A).
(iii) Rs (=Rs1+Rs2) and Re (=RE1 resistance) value control the Idebias vs. Vcc slope in the mid Vcc range.
(iv) Rc (=RC1 resistance) and D2 control the Q10 device Vce headroom and limit Idebias at high Vcc levels, as shown in FIGS. 5A and 5B.
(v) Q11 is switched on and off by an external Ven supply. When Q11 is on, it works in saturation mode and its saturation Vce is very low (<0.2 V for a GaAs HBT process, as shown in FIG. 5B).

$${I}_{debias} = β \cdot {I}_{sense} = \frac{{V}_{cc} - {V}_{F}^{D 1} - {V}_{BE}^{Q 10} - {V}_{CE}^{Sat}}{\frac{{R}_{s} + {R}_{e}}{β} + {R}_{e}} \qquad EQ . 2$$

In (v), the on-state external Ven supply voltage needs to be higher than the combined turn-on voltage of D3 and Q11 as expressed by Equation 3. Equation 4 shows the Ren condition to drive Q11 into saturation mode during the on-state. A practical guideline is to have the left-hand side of the inequality be ˜0.1× the right-hand side. On the other hand, when Ren is too low, it causes excessive current draw from the Ven supply. Ren and D3 should be co-designed with the Ven supply specifications. During the power amplifier off mode, Vcc can be high but Ven and Ireg are off, turning Q11 off and presenting an open circuit to stop any current leakage through it. To restrict the Icc leakage completely, D2 serves a second purpose by stopping reverse current flow going from the Q10 B-C diode to Q7, Q8, and GND1. The addition of Q10 and D2 to remove supply adaptive biasing leakage current makes is an advantageous feature of the architecture according to the present disclosure.

$$Ven > {V}_{F}^{D 3} + {V}_{BE}^{Q 11} \qquad EQ . 3$$

$${R}_{en} ≪ \frac{Ven - {V}_{F}^{D 3} - {V}_{BE}^{Q 11}}{{V}_{cc}^{max} - {V}_{F}^{D 1} - {V}_{BE}^{Q 10} - {V}_{CE}^{Sat}} \cdot ( {R}_{s} + {R}_{e} + β {R}_{e} ) \qquad EQ . 4$$

A general embodiment of the supply adaptive biasing to control power amplifier bias is also depicted in FIG. 4, where the Idebias tapping location can be any node along the reference current path of the bias network, as labelled with “A”, “B,” and “C.” The BJT devices in the supply adaptive biasing can be replaced with field-effect transistor (FET) devices when they are available. Q10 in FIG. 4 is used to scale Idebias from the sensed Vcc. Q11 in FIG. 4 is used to switch on and off the supply adaptive biasing. When implemented with a BJT, the BJT operates in saturation mode to achieve low Vce drop and in off-mode to present as an open circuit to GND. When a FET is used, the FET is simply in on and off mode. The diodes D1, D2, and D3 can either be regular diodes or diode connection of three-terminal devices such as BJTs or FETs. As alternatives, D1 and D2 can be removed when low Vcc range is specified. D3 diode placement according to the present disclosure is to level shift the base voltage of Q11 and hence can be removed as well when the supplied Ven is only slightly above Q11 Vbe. Rs is split into Rs1 and Rs2 in FIG. 4 for design flexibility of filtering time constant. Rs1 and Rs2 can be merged into one. Cfil2 can be removed if the sensed Vcc is deemed clean enough.

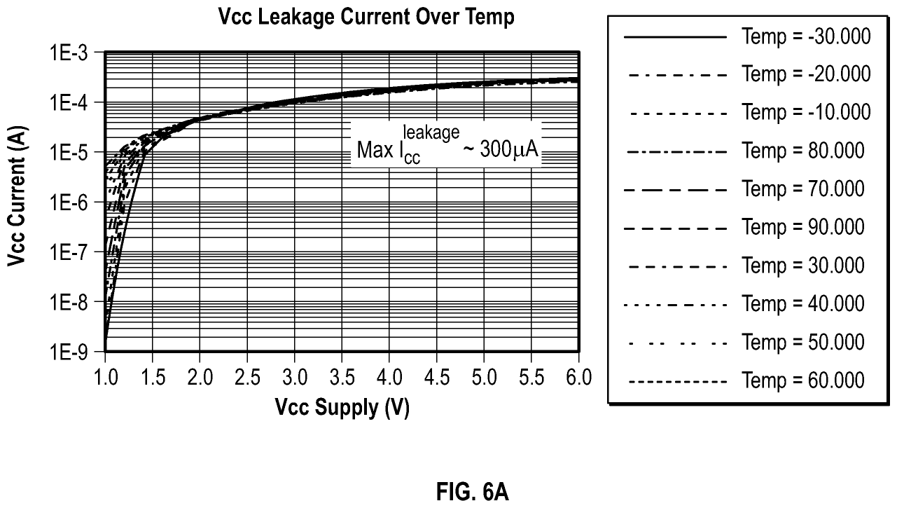

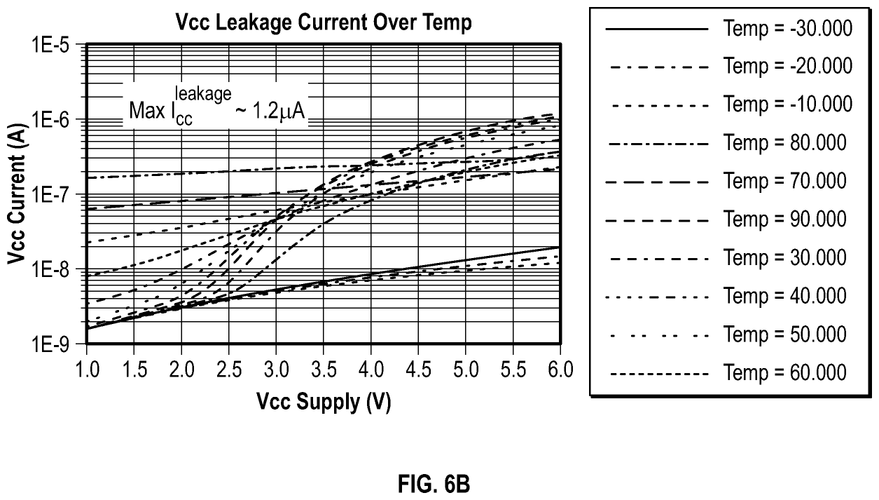

After careful design, the desired pQ2 (i.e., Q5 and Q6) bias vs. Vcc profiles are shown in the solid line traces in FIG. 5C and FIG. 5D. At the high Vcc region, the pQ2 is biased at class “C” as desired in a canonical Doherty power amplifier design. As the Vcc decreases, the pQ2 quiescent current, Icq, is pulled up to class “B” and then “AB” at the extremely low Vcc levels. This bias profile is intended to compensate for the weaker RF-regulated self-biasing in the low Vcc region. Furthermore, the Vcc leakage current reduction according to the present disclosure is demonstrated in FIG. 6. FIG. 6A plots out the leakage current of the supply adaptive biasing Doherty power amplifier without the consideration in this regard by removing Q11 and D2. A maximum of 300 μA Vcc leakage is simulated over the extreme conditions and it grossly fails a typical handset TX module's specification of 10 μA. In FIG. 6B the complete embodiment according to the present disclosure shows a maximum 1.2 μA Vcc leakage over the same extreme conditions, meeting the current leakage specification with good margin.

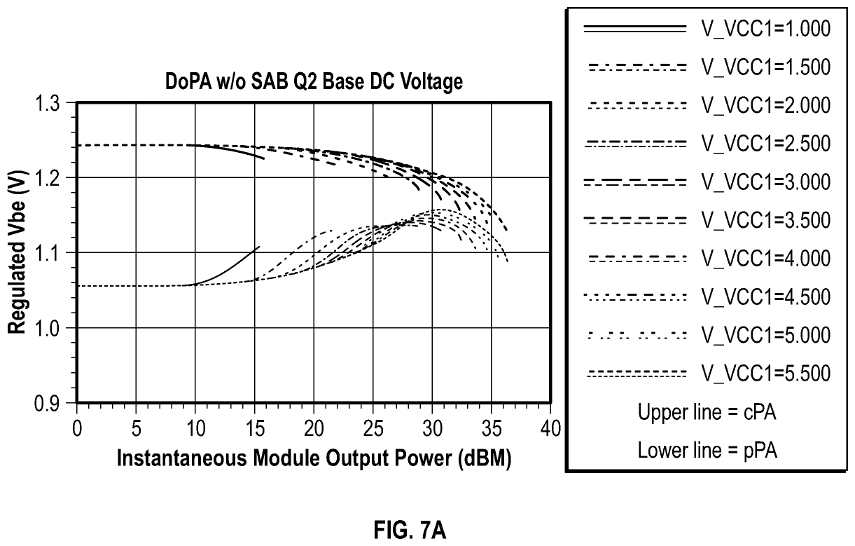

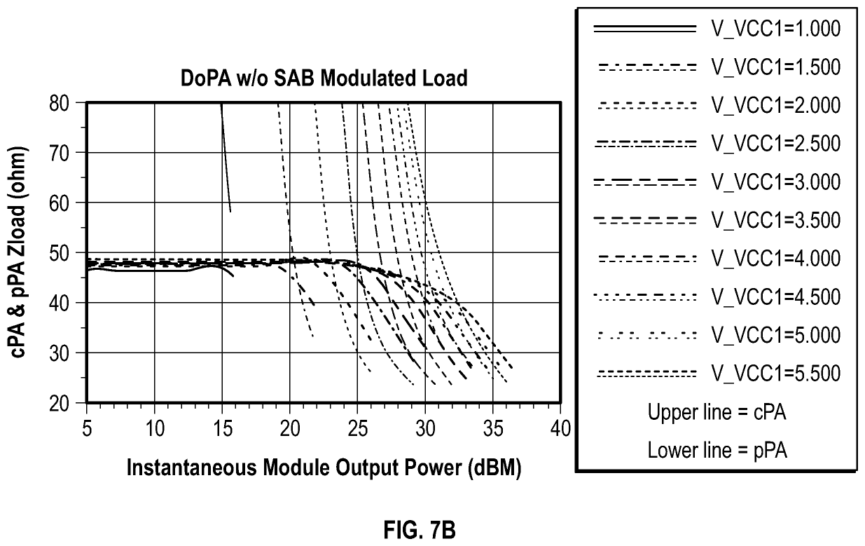

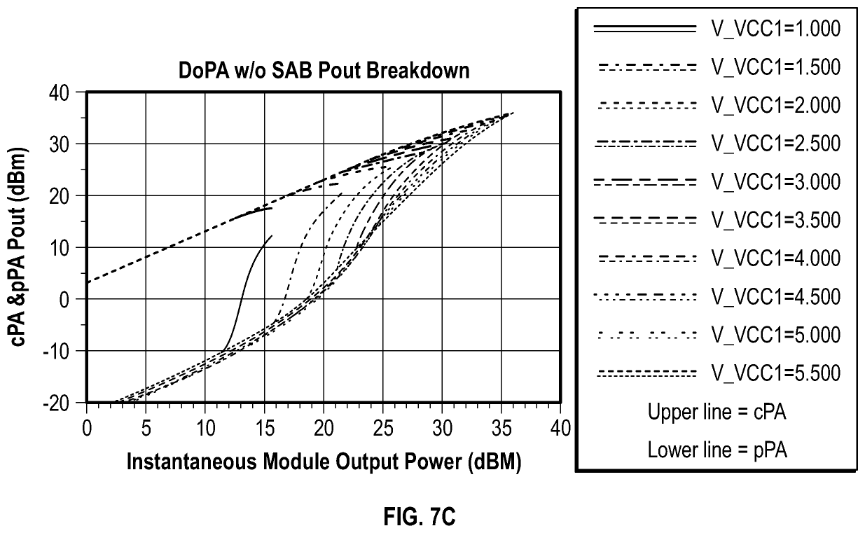

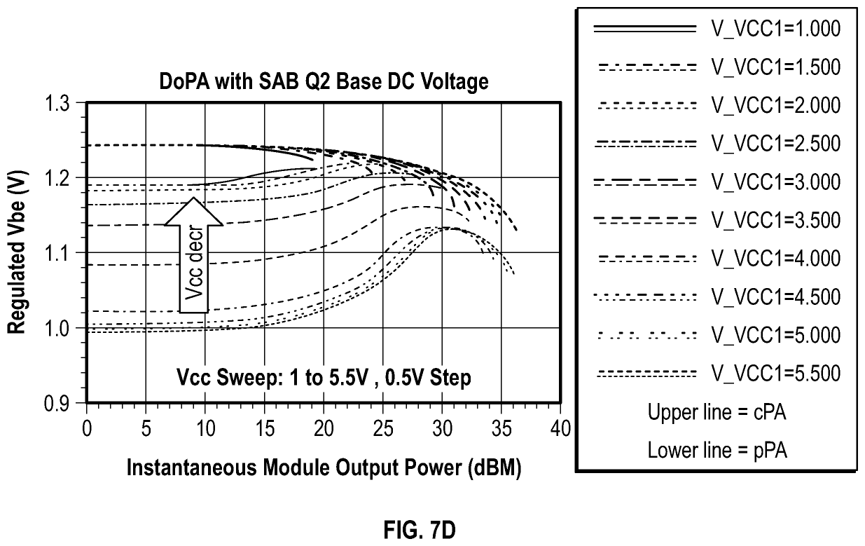

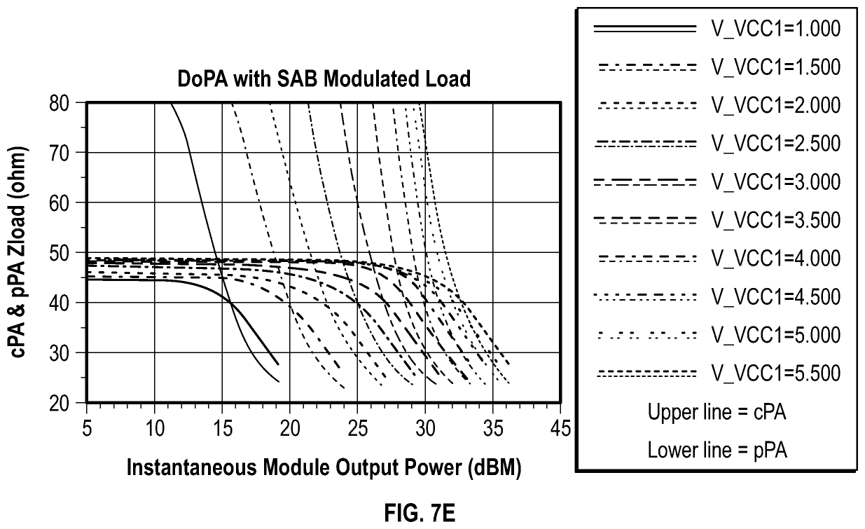

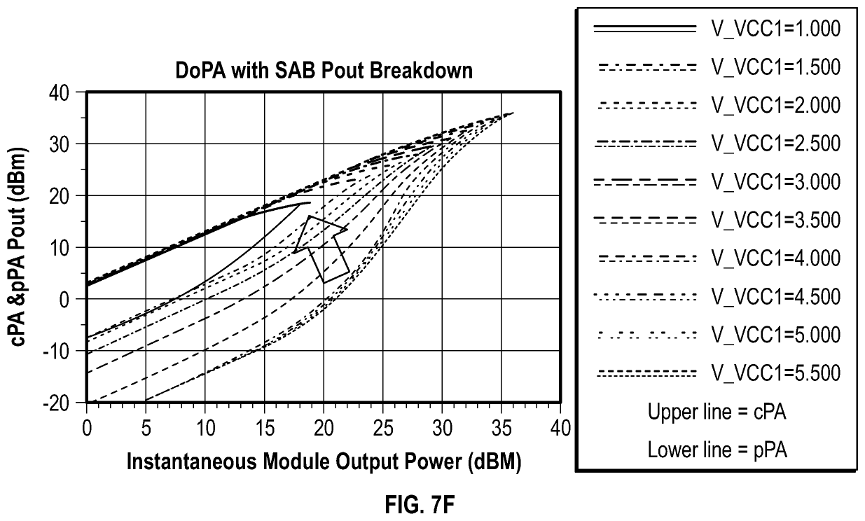

FIG. 7 analyzes the Doherty power amplifier bias, load modulation, and the output power breakdown during the power and Vcc sweep. Based on Doherty power amplifier theoretical load-line design, the simulated carrier amplifier load is expected to travel from 48 ohm in low/mid power region to the targeted 24 ohm at peak power. Correspondingly, the peaking amplifier load should move from very high impedance to the targeted 24 ohm at peak power. The actual simulated peak power loads drift slightly due to the effect of the harmonic termination of the power amplifier on power amplifier performance. The plots of FIGS. 7A, 7B, and 7C show the operating conditions of the Doherty power amplifier without supply adaptive biasing, and the plots of FIGS. 7D, 7E, and 7F with supply adaptive biasing. For the fixed bias Doherty power amplifier, both the carrier amplifier and peaking amplifier bias stay constant in the low power region when the supply Vcc is swept from 1 V to 5.5 V, as shown in FIG. 7A. In the high power region, these bias points move due to RF regulated self-biasing. FIG. 7B shows the root cause of the performance degradation in the low Vcc region (Vcc≤3.5 V). Although the load modulation happens as expected over power drive in the high Vcc region, the load modulation weakens significantly in the low Vcc region. Both the carrier amplifier and peaking amplifier miss their peak power load targets at low Vcc. Consequently, both power amplifiers suffer peak Pout loss at low Vcc, as shown in FIG. 7C. When the supply adaptive biasing according to the present disclosure is implemented in the Doherty power amplifier, the supply adaptive biasing adaptively biases the peaking amplifier 14 according to the Vcc value as shown in FIG. 7D. The benefit is shown in FIG. 7E, where both the carrier amplifier and the peaking amplifier loads are now optimally modulated down to the peak power targets at all Vcc levels. FIG. 7F illustrates how the output power POUT of the second stage 14 has improved significantly at low Vcc, and the power contributed by the first carrier power transistor Q3, the second carrier power transistor Q4, the first peaking power transistor Q5, and the second peaking power transistor Q6 intercept in the plot for all Vcc values, as desired for symmetrical Doherty power amplifier operation, that is, equal peak Pout between carrier and peaking amplifiers.

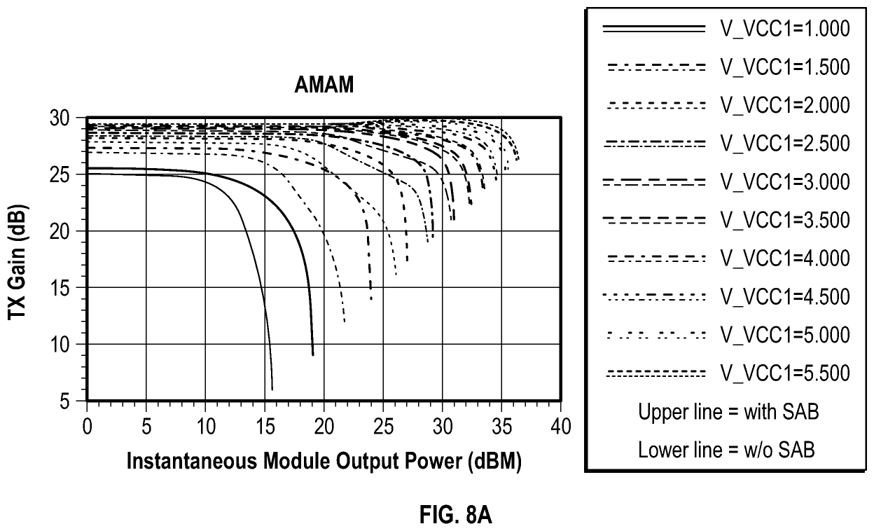

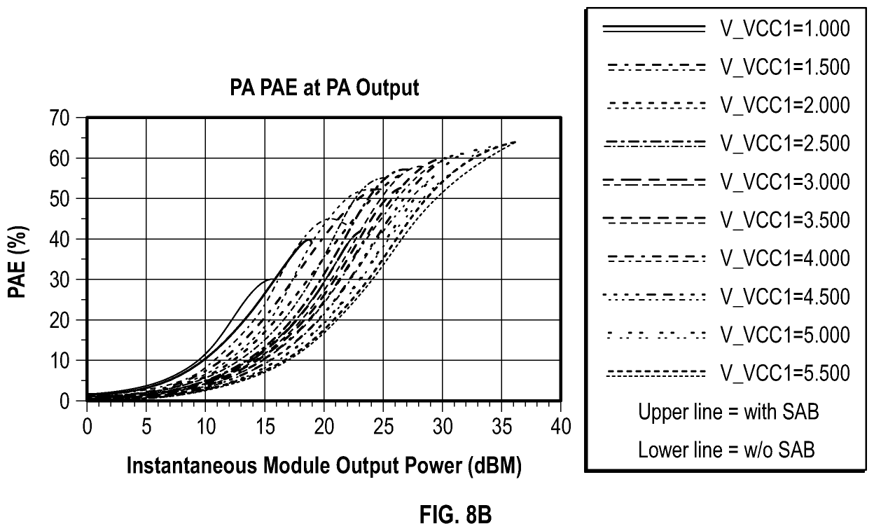

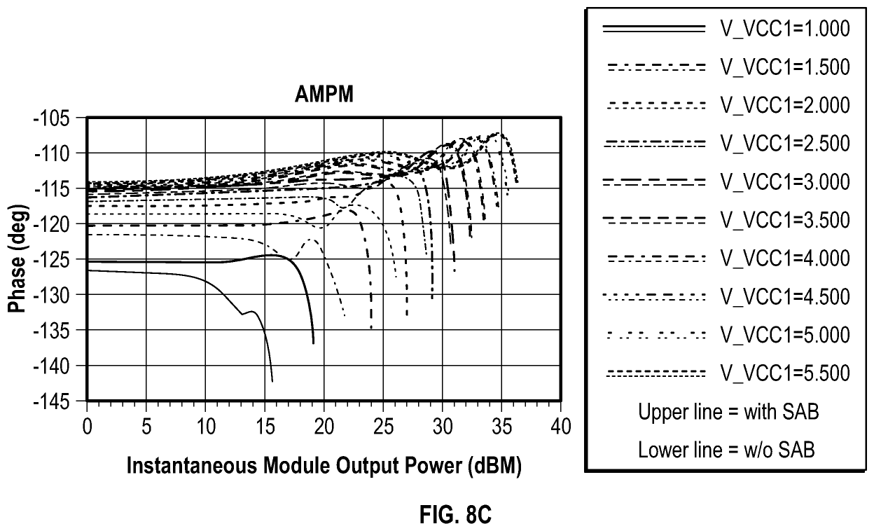

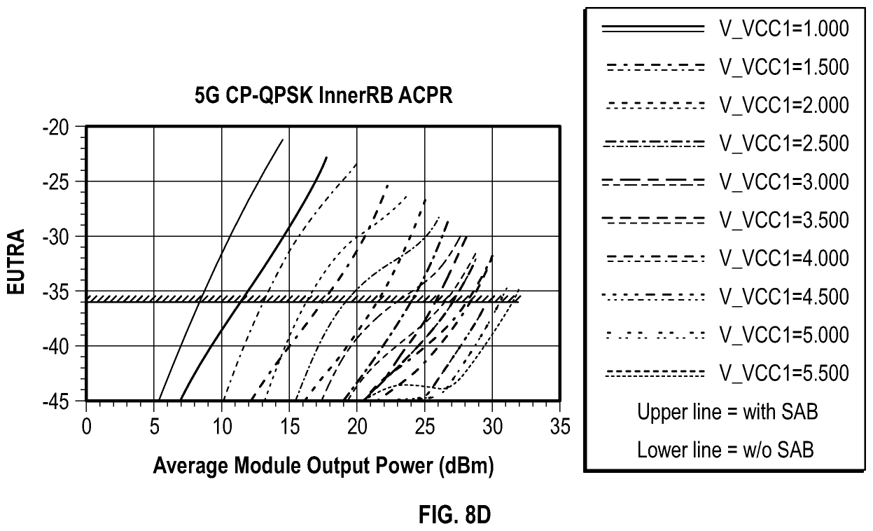

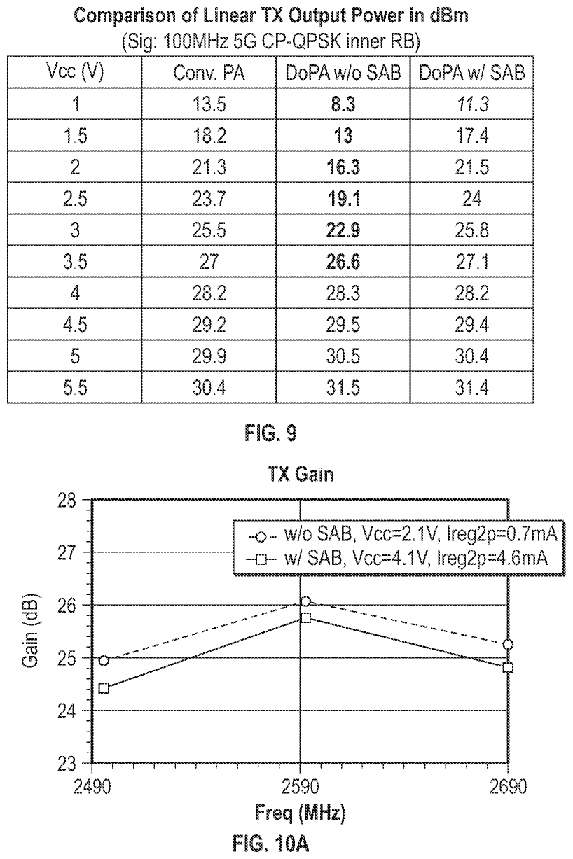

The AMAM and amplitude modulation-phase modulation (AMPM) plots in FIGS. 8A and 8C, respectively, show significant continuous wave performance improvement in the low Vcc region for the Doherty power amplifier with the supply adaptive biasing as disclosed compared with the Doherty power amplifier without the supply adaptive biasing. The 5G CP-QPSK simulated EUTRA adjacent channel power (ACP) plot (FIG. 8D) also shows significant linear power improvement as a result. Only negligible AMAM and AMPM impact is observed in the high Vcc region. The power amplifier PAE plot (FIG. 8B) shows no negative impact from the supply adaptive biasing across Vcc and actually has improved PBO efficiency at the high Vcc region. The tabulated linear Pout at the module output is summarized in FIG. 9 with the conventional non-Doherty power amplifier also included as a reference. Note that the Doherty power amplifiers show very similar or higher Pout than conventional power amplifier for Vcc>3.5 V in this example design. As Vcc drops below 3.5 V, the Doherty power amplifier without the supply adaptive biasing shows significant loss of Pout, but the supply adaptive biasing fixes the Pout issue, as shown in the last column of FIG. 9. At 1 V, the supply adaptive biasing Doherty power amplifier still lacks a couple of decibels of power compared with the reference design, and this can be fixed with further optimization of bias currents and a quiescent current profile change, potentially at the tradeoff of efficiency.

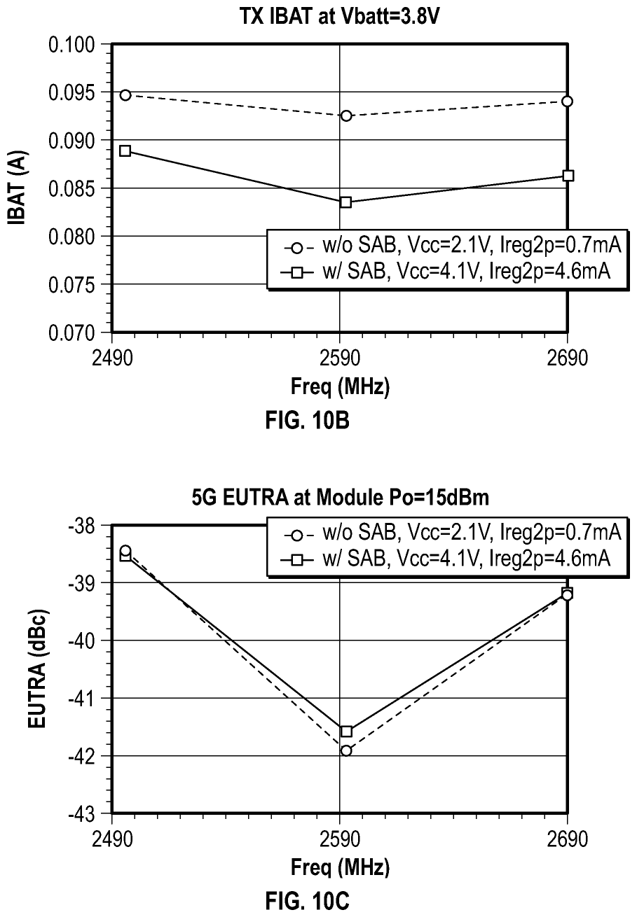

FIGS. 10A, 10B, and 10C are graphs showing a Doherty power amplifier modulated signal simulation at module Avg Po=15 dBm in n41 band: Signal: 100 MHz 5G CP-QPSK inner RB; DC-DC converter eff=92% in computation of Ibatt. Note that for the baseline Doherty power amplifier without the supply adaptive biasing, Vcc needs to be raised to overcome the power loss. The pQ2 Ireg2P values were found through performance optimization, and the rest of the power stages are biased at the identical values between the two power amplifiers. The two power amplifiers have very similar gain and EUTRA ACP performance. However, the disclosed embodiment of the Doherty power amplifier 10 with supply adaptive biasing shows about 10% Ibatt current savings in the n41 band.

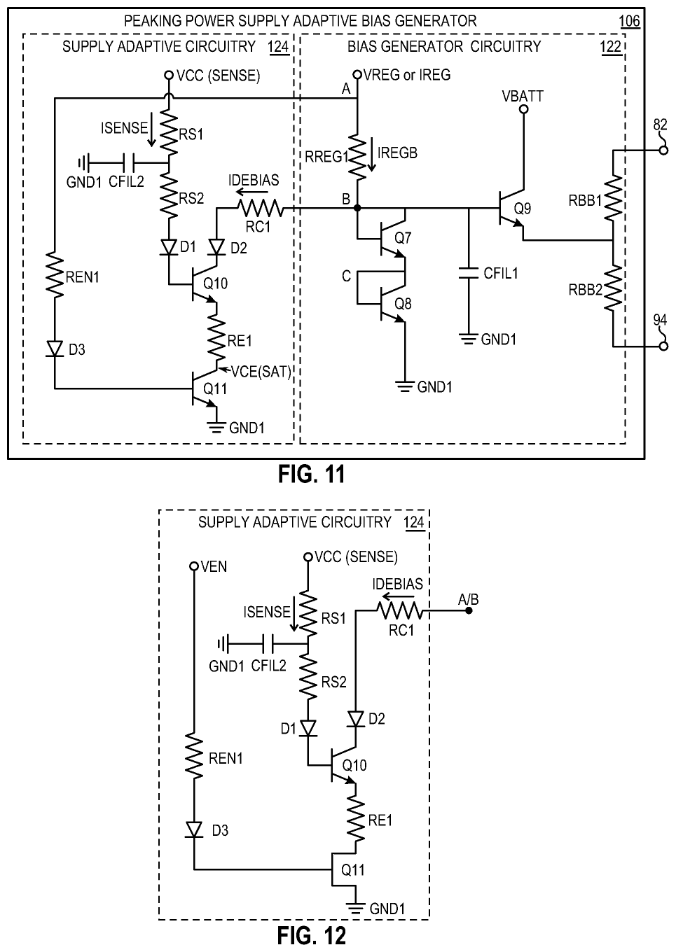

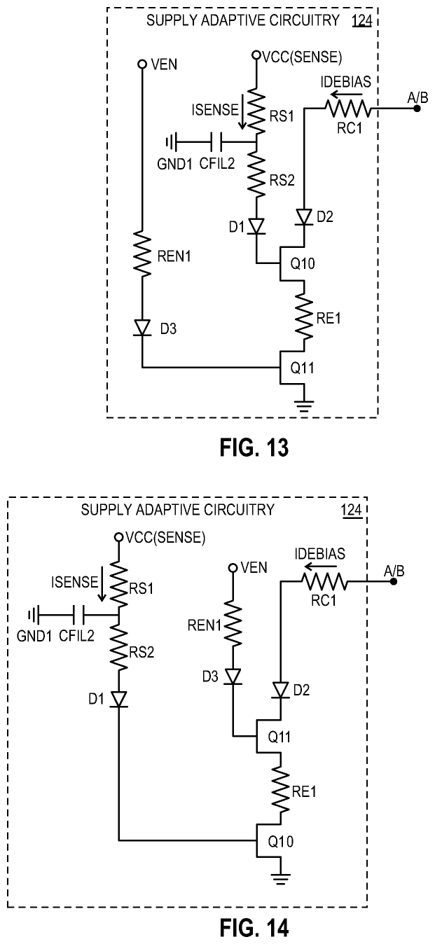

Alternative embodiments include, but are not limited to, the following:
1. An alternative implementation of the dashed box in FIG. 4 by removing D1 or removing D2 or removing D3 or removing any combination of D1, D2, and D3.
2. Another alternative implementation of the embodiment of FIG. 4 by removing Rs1 and Cfil2 if sensed Vcc has a relatively low level of radio frequency energy.
3. An alternative embodiment by supplying Ven from the power amplifier bias Vreg or Ireg directly, as shown in FIG. 11. This is feasible since the power amplifier bias voltage is at least 2×Vbe of BJT devices, and thus is high enough to drive Q11. Vreg or Ireg is usually turned off when power amplifier is off. This embodiment saves an external Ven supply, thus simplifying implementation according to the present disclosure.
4. An alternative embodiment of supply adaptive biasing is shown in FIG. 12. Q11 is replaced with a FET device when it is available from the process. If Q11 is a complementary metal oxide semiconductor (CMOS) device, Ren and D3 may be removed.
5. Another alternative embodiment of supply adaptive biasing is shown in FIG. 13. Both Q10 and Q11 are implemented with FET devices. When Q11 is a CMOS device, REN1 and D3 can be removed. When Q10 is a CMOS device, RS2 and D1 and RE1 can be removed.
6. Another alternative embodiment of supply adaptive biasing is shown in FIG. 14. Both Q10 and Q11 are implemented with CMOS devices and their placement locations are swapped. In this embodiment, REN1 and D3 can be removed. RS2 and D1 can also be removed.

In operation, in the present method the peaking power supply adaptive bias generator 106 is configured to sense supply voltage to the peaking amplifier (i.e., Q5 and Q6) and to increase bias currents to the peaking output transistors as the supply voltage decreases. In exemplary embodiments, the method further includes steps of controlling magnitudes of the bias currents to the peaking output transistors in response to a debias current flowing through the bias control node A/B, and adjusting the debias current flowing through the debias current branch in response to changes in the supply voltage.

Moreover, the supply adaptive circuitry 124 is configured to progressively reduce the debias current sink from the bias control node A/B of the bias generator circuitry 122 as the supply voltage decreases. The method further includes a step of increasing bias currents to the peaking output transistors in response to the reduced debias current.

Further still, the supply adaptive circuitry 124 is configured to progressively increase the debias current sink from the bias control node A/B of the bias generator circuitry 122 as the supply voltage increases. The method further includes a step of decreasing bias currents to the peaking output transistors in response to the increased debias current.

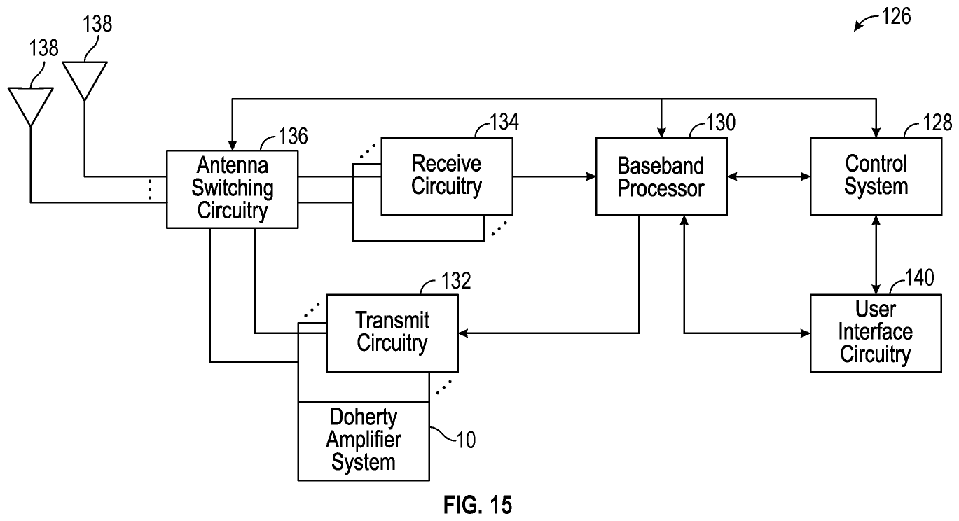

With reference to FIG. 15, the concepts described above may be implemented in various types of wireless communication devices or user elements 126, such as mobile terminals, smart watches, tablets, computers, navigation devices, access points, and the like that support wireless communications, such as cellular, wireless local area network (WLAN), Bluetooth, and near-field communications. The user elements 126 generally include a control system 128, a baseband processor 130, transmit circuitry 132, receive circuitry 134, antenna switching circuitry 136, multiple antennas 138, and user interface circuitry 140. The receive circuitry 134 receives radio frequency signals via the antennas 138 and through the antenna switching circuitry 136 from one or more basestations. A low-noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams.

The baseband processor 130 processes the digitized received signal to extract the information or data bits conveyed in the received signal. This processing typically comprises demodulation, decoding, and error correction operations. The baseband processor 130 is generally implemented in one or more digital signal processors (DSPs) and application-specific integrated circuits (ASICs). For transmission, the baseband processor 130 receives digitized data, which may represent voice, data, or control information, from the control system 128, which it encodes for transmission. The encoded data is output to the transmit circuitry 132, where it is used by a modulator to modulate a carrier signal that is at a desired transmit frequency or frequencies. The Doherty power amplifier system 10 will amplify the modulated carrier signal to a level appropriate for transmission and deliver the modulated carrier signal to the multiple antennas 138 through the antenna switching circuitry 136. The multiple antennas 138 and the replicated transmit circuitry 132 and receive circuitry 134 may provide spatial diversity. Modulation and processing details will be understood by those skilled in the art.

Those skilled in the art will recognize improvements and modifications to the present disclosure. All such improvements and modifications are considered within the scope of the concepts disclosed herein.

1. An amplifier comprising:
a carrier amplifier;
a peaking amplifier coupled in parallel with the carrier amplifier, wherein the peaking amplifier is comprised of peaking output transistors configured to amplify a signal input to the peaking amplifier and coupled in a differential amplifier configuration; and
a peaking power supply adaptive bias generator coupled to bias control terminals of the peaking output transistors, wherein the peaking power supply adaptive bias generator is configured to sense supply voltage to the peaking amplifier and increase bias currents to the peaking output transistors as the supply voltage decreases.

2. The amplifier of claim 1 wherein the peaking power supply adaptive bias generator comprises:
bias generator circuitry having a bias control node, and a bias output coupled to bias control inputs of the peaking output transistors, wherein the bias generator circuitry controls magnitudes of the bias currents to the peaking output transistors in response to a debias current flowing through the bias control node; and
supply adaptive circuitry having a supply voltage sense terminal configured to receive the supply voltage powering the peaking amplifier, and a debias current branch coupled to the bias control node, wherein the supply adaptive circuitry is configured to adjust the debias current flowing through the debias current branch in response to changes in the supply voltage.

3. The amplifier of claim 2 wherein the supply adaptive circuitry is configured to:
progressively reduce the debias current sink from the bias control node of the bias generator circuitry as the supply voltage decreases; and
correspondingly, the bias generator circuitry is configured to increase bias currents to the peaking output transistors in response to the reduced debias current.

4. The amplifier of claim 2 wherein the supply adaptive circuitry is configured to:
progressively increase the debias current sink from the bias control node of the bias generator circuitry as the supply voltage increases; and
correspondingly, the bias generator circuitry is configured to decrease bias currents to the peaking output transistors in response to the increased debias current.

5. The amplifier of claim 2 wherein the bias generator circuitry comprises a bias generator transistor having a base coupled to the bias control node, a collector coupled to a voltage source, and an emitter coupled to the bias control terminals of the peaking output transistors.

6. The amplifier of claim 5 wherein the bias generator circuitry further comprises a filter capacitor coupled between the base and a fixed voltage node.

7. The amplifier of claim 2 wherein the supply adaptive circuitry comprises a debias transistor and an enable transistor coupled in series within the debias current branch, wherein debias current flows through the debias transistor and enable transistor when the enable transistor is in an enabled state and wherein no debias current flows through the debias transistor and the enable transistor when the enable transistor is in a disabled state.

8. The amplifier of claim 7 wherein the debias transistor and the enable transistor are both bipolar transistors.

9. The amplifier of claim 7 wherein the debias transistor and the enable transistor are both field-effect transistors.

10. The amplifier of claim 7 wherein the debias transistor is a bipolar transistor and the enable transistor is a field-effect transistor.

11. The amplifier of claim 7 wherein the debias transistor has a debias control terminal coupled to a supply voltage sense terminal that is configured to receive the supply voltage, and the enable transistor has an enable control coupled to an enable terminal that is configured to receive enable/disable voltage levels that place the enable transistor in the enabled state and the disabled state.

12. The amplifier of claim 7 wherein the debias current branch further comprises a debias diode coupled in series with the debias transistor and the enable transistor.

13. The amplifier of claim 7 further comprising an enable diode coupled between the enable control and the enable terminal.

14. The amplifier of claim 7 further comprising a sense diode coupled between the debias control terminal and the supply voltage sense terminal.

15. The amplifier of claim 7 further comprising a low-pass filter coupled between the supply voltage sense terminal and the debias control terminal, wherein the low-pass filter is configured to remove radio frequency noise from the supply voltage at the supply voltage sense terminal.

16. A method for amplifying signals using a carrier amplifier and a peaking amplifier coupled in parallel with the carrier amplifier wherein the peaking amplifier is comprised of peaking output transistors configured to amplify a signal input to the peaking amplifier and coupled in a differential amplifier configuration, and a peaking power supply adaptive bias generator coupled to bias control terminals of the peaking output transistors, the method comprising a step of configuring the peaking power supply adaptive bias generator to sense supply voltage to the peaking amplifier and increase bias currents to the peaking output transistors as the supply voltage decreases.

17. The method of claim 16, wherein the peaking power supply adaptive bias generator comprises a bias generator circuitry having a bias control node, and a bias output coupled to bias control inputs of the peaking output transistors, and supply adaptive circuitry having a supply voltage sense terminal and a debias current branch coupled to the bias control node, the method further comprising steps of:
controlling magnitudes of the bias currents to the peaking output transistors in response to a debias current flowing through the bias control node; and
adjusting the debias current flowing through the debias current branch in response to changes in the supply voltage.

18. The method of claim 17, wherein the supply adaptive circuitry is configured to progressively reduce the debias current sink from the bias control node of the bias generator circuitry as the supply voltage decreases, the method further comprising a step of increasing bias currents to the peaking output transistors in response to the reduced debias current.

19. The method of claim 17, wherein the supply adaptive circuitry is configured to progressively increase the debias current sink from the bias control node of the bias generator circuitry as the supply voltage increases, the method further comprising a step of decreasing bias currents to the peaking output transistors in response to the increased debias current.

20. A wireless communication device comprising:
a baseband processor;
transmit circuitry configured to receive encoded data from the baseband processor and modulate a radio frequency signal with the encoded data, wherein the transmit circuitry comprises:
a carrier amplifier;
a peaking amplifier coupled in parallel with the carrier amplifier, wherein the peaking amplifier is comprised of peaking output transistors coupled in a differential amplifier configuration; and
a peaking power supply adaptive bias generator coupled to bias control terminals of the peaking output transistors, wherein the peaking power supply adaptive bias generator is configured to sense supply voltage to the peaking amplifier and increase bias currents to the peaking output transistors as the supply voltage decreases.

21. The wireless communication device of claim 20 wherein the peaking power supply adaptive bias generator comprises:
bias generator circuitry having a bias control node, and a bias output coupled to bias control inputs of the peaking output transistors, wherein the bias generator circuitry controls magnitudes of the bias currents to the peaking output transistors in response to a debias current flowing through the bias control node; and
supply adaptive circuitry having a supply voltage sense terminal configured to receive the supply voltage powering the peaking amplifier, and a debias current branch coupled to the bias control node, wherein the supply adaptive circuitry is configured to adjust the debias current flowing through the debias current branch in response to changes in the supply voltage.

22. The wireless communication device of claim 21 wherein the supply adaptive circuitry is configured to:
progressively reduce the debias current sink from the bias control node of the bias generator circuitry as the supply voltage decreases; and
correspondingly, the bias generator circuitry is configured to increase bias currents to the peaking output transistors in response to the reduced debias current.

23. The wireless communication device of claim 21 wherein the supply adaptive circuitry is configured to:
progressively increase the debias current sink from the bias control node of the bias generator circuitry as the supply voltage increases; and
correspondingly, the bias generator circuitry is configured to decrease bias currents to the peaking output transistors in response to the increased debias current.

24. The wireless communication device of claim 21 wherein the bias generator circuitry comprises a bias generator transistor having a base coupled to the bias control node, a collector coupled to a voltage source, and an emitter coupled to the bias control terminals of the peaking output transistors.

25. The wireless communication device of claim 24 wherein the bias generator circuitry further comprises a filter capacitor coupled between the base and a fixed voltage node.

26. The wireless communication device of claim 21 wherein the supply adaptive circuitry comprises a debias transistor and an enable transistor coupled in series within the debias current branch, wherein debias current flows through the debias transistor and enable transistor when the enable transistor is in an enabled state and wherein no debias current flows through the debias transistor and the enable transistor when the enable transistor is in a disabled state.

27. The wireless communication device of claim 26 wherein the debias transistor and the enable transistor are both bipolar transistors.

28. The wireless communication device of claim 26 wherein the debias transistor and the enable transistor are both field-effect transistors.

29. The wireless communication device of claim 26 wherein the debias transistor is a bipolar transistor and the enable transistor is a field-effect transistor.

30. The wireless communication device of claim 26 wherein the debias transistor has a debias control terminal coupled to a supply voltage sense terminal that is configured to receive the supply voltage, and the enable transistor has an enable control coupled to an enable terminal that is configured to receive enable/disable voltage levels that place the enable transistor in the enabled state and the disabled state.

31. The wireless communication device of claim 26 wherein the debias current branch further comprises a debias diode coupled in series with the debias transistor and the enable transistor.

32. The wireless communication device of claim 26 further comprising an enable diode coupled between the enable control and the enable terminal.

33. The wireless communication device of claim 26 further comprising a sense diode coupled between the debias control terminal and the supply voltage sense terminal.

34. The wireless communication device of claim 26 further comprising a low-pass filter coupled between the supply voltage sense terminal and the debias control terminal, wherein the low-pass filter is configured to remove radio frequency noise from the supply voltage at the supply voltage sense terminal.
